(19) United States
(12) Patent Application Publication
(10) Pub. No.: US 2026/0181998 A1
(43) Pub. Date: Jun. 25, 2026

(54) CONTACT AND METHODS OF FORMING SAME

(71) Applicant: Taiwan Semiconductor Manufacturing Company, Ltd., Hsin-Chu (TW)

(72) Inventors: Hao-Chin Huang, Kaohsiung City (TW); Ting-Hsuan Lai, New Taipei City (TW); Wei-Yip Loh, Hsinchu City (TW); Chun-Hsien Huang, Hsinchu (TW)

(21) Appl. No.: 19/197,031

(22) Filed: May 2, 2025

Related U.S. Application Data
(60) Provisional application No. 63/738,311, filed on Dec. 23, 2024.

(51) Int. Cl. H10D 84/01; H01L 21/285; H01L 21/3213

(52) U.S. Cl. CPC H10D 84/0149; H10D 64/0112; H10P 50/267

(57) ABSTRACT

A method includes providing a structure including a bottom device and a top device over the bottom device, forming a trench extending through the top device and into the bottom device, and forming a conductive plug in the trench. The trench includes a bottom portion having a first width and a top portion having a second width, the first width is less than the second width. Forming the conductive plug in the trench includes depositing a metal precursor over the structure, thereby forming a metal layer in the top and bottom portions of the trench, performing an etch-back process to a top portion of the metal layer, filling a metal fill layer in the trench, and performing a planarization process to the structure.

### PRIORITY DATA

This is a non-provisional application of and claims the benefit of U.S. Provisional Application No. 63/738,311 filed Dec. 23, 2024, the entirety of which is incorporated herein by reference.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

Such scaling down has also increased the complexity of processing and manufacturing ICs and, for these advances to be realized, similar developments in IC processing and manufacturing are needed. For example, stacked device structures are introduced to enable further density reduction for advanced IC technology nodes. However, fabrication of such stacked device structures introduces more challenges. As a result, existing implementations have not been satisfactory in all respects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1 illustrates a flowchart of a method for forming a semiconductor structure, according to one or more aspects of the present disclosure.

FIGS. 2, 3, 4A, 8, and 9 illustrate fragmentary cross-sectional views of an exemplary semiconductor structure during various fabrication stages in the method of FIG. 1, according to one or more aspects of the present disclosure.

FIGS. 4B, 5A, 5B, 6, 7A, and 7B illustrate fragmentary schematic cross-sectional views of an exemplary semiconductor structure during various fabrication stages in the method of FIG. 1, according to one or more aspects of the present disclosure.

FIG. 10 illustrates a flowchart of a method for forming a semiconductor structure, according to one or more aspects of the present disclosure.

FIGS. 11A, 11B, 12A, 12B, 13A, 13B, 14A, and 14B illustrate fragmentary schematic cross-sectional views of an exemplary semiconductor structure during various fabrication stages in the method of FIG. 10, according to one or more aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +−15% by one of ordinary skill in the art.

Stacked transistor structures can provide further density reduction for advanced integrated circuit (IC) technology nodes (particularly as they advance to 3 nm (N3) and below), especially when the stacked transistor structures include multigate devices, such as fin-like field effect transistors (FinFETs), gate-all-around (GAA) transistors including nanowires and/or nanosheets, other types of multigate devices, etc. Stacked transistor structures include vertically stacked transistors. For example, a stacked transistor structure can include a first transistor (i.e., an upper/top transistor) disposed over a second transistor (i.e., a lower/bottom transistor). The transistor stack can provide a complementary field effect transistor (CFET) when the first transistor and the second transistor are of opposite conductivity type (i.e., an n-type transistor and a p-type transistor).

The stacked transistor structures may include source/drain contacts. In some cases, the stacked n-type and p-type transistors share a common source/drain contact. The common source/drain contact may be a local interconnect for connecting n-type and p-type source/drain epitaxial features together. Since the n-type and p-type epitaxial features are stacked vertically one over the other, the local interconnect may need to penetrate through the top epitaxial feature until it lands on the bottom epitaxial feature. However, forming the source/drain contacts in stacked devices involve various challenges, such as higher resistance. Therefore, although existing stacked device structures (e.g., CFET structures) and their related fabrication processes have been generally adequate for their intended purposes, they have not been entirely satisfactory in every aspect.

The present disclosure is generally related to semiconductor structures (e.g., stacked transistor structures) having a common source/drain contact. In an example process, a structure (e.g., a CFET structure) is provided. The structure includes a bottom transistor disposed over a substrate and a top transistor disposed over the bottom transistor. The bottom transistor includes a bottom source/drain feature and the top transistor includes a top source/drain feature vertically above the bottom source/drain feature. A trench is formed to expose the bottom source/drain feature and the top source/drain feature. A metal seed layer is deposited along sidewalls and bottom surfaces of the trench. A deposition process is performed including depositing a metal precursor and a reactive agent, thereby forming a metal layer in the trench. In some embodiments, a metal self-etching process is performed by flowing the metal precursor at an increased concentration over the structure, thereby removing top portions of the metal layer and the metal seed layer. The deposition process and the metal self-etching process may be repeated until a bottom portion of the trench is filled without a seam therein. In some other embodiments, after the deposition process, a bottom antireflective coating (BARC) layer is deposited over the metal layer and in a top portion of the trench. A pull-back process is performed to remove portions of the metal layer and the metal liner above the BARC layer. The BARC layer is then removed. A metal fill layer is then deposited in the trench and a planarization process is performed to remove excess materials, thereby forming the common source/drain contact. By forming the source/drain contact using the method in the present disclosure, a seam may be avoided or have a reduced size in the source/drain contact, thus the resistance of the source/drain contact is reduced.

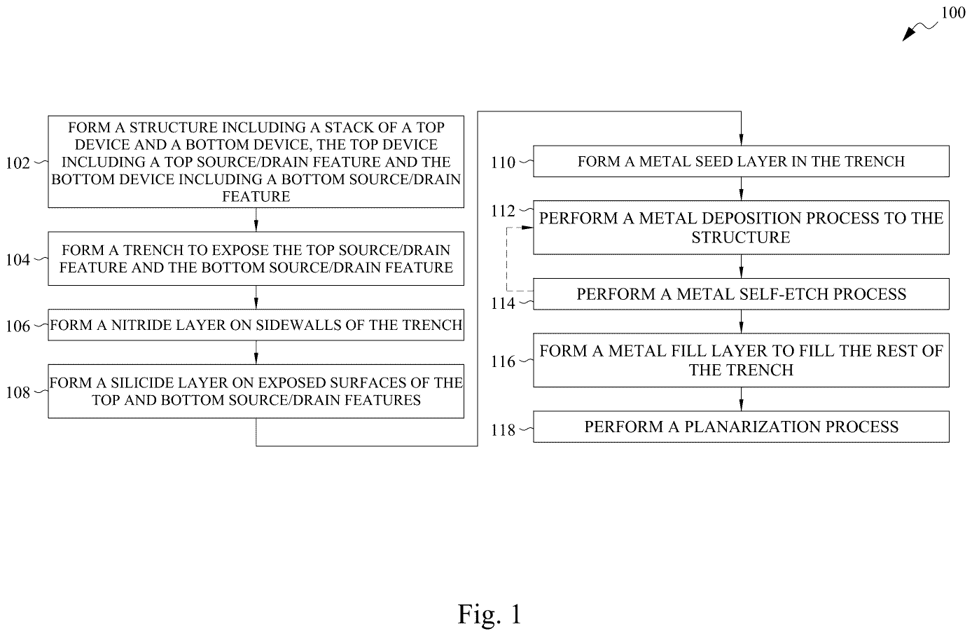

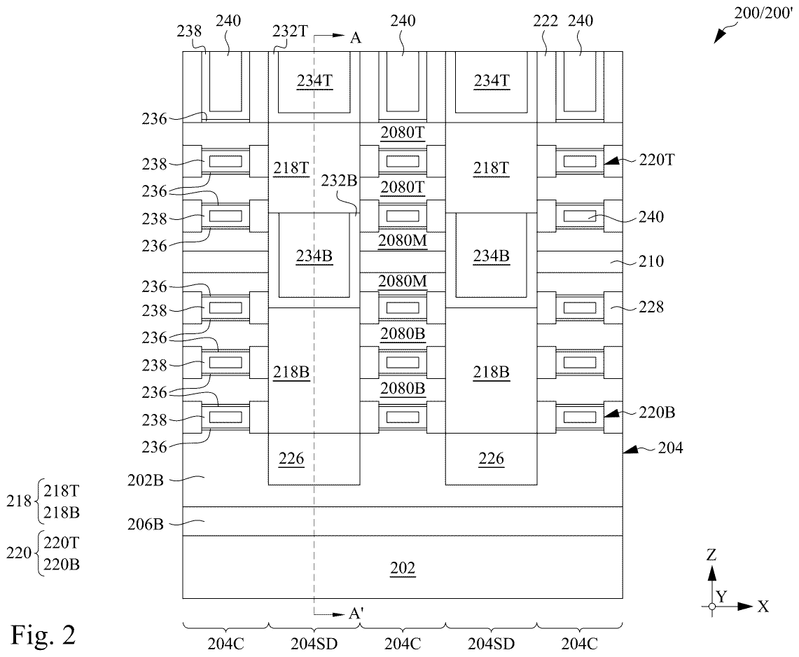

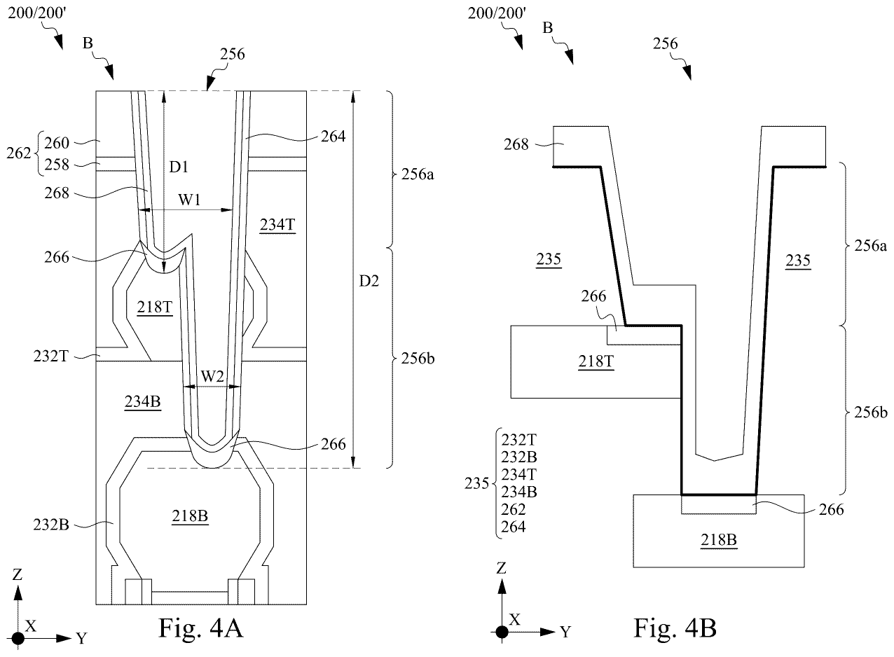

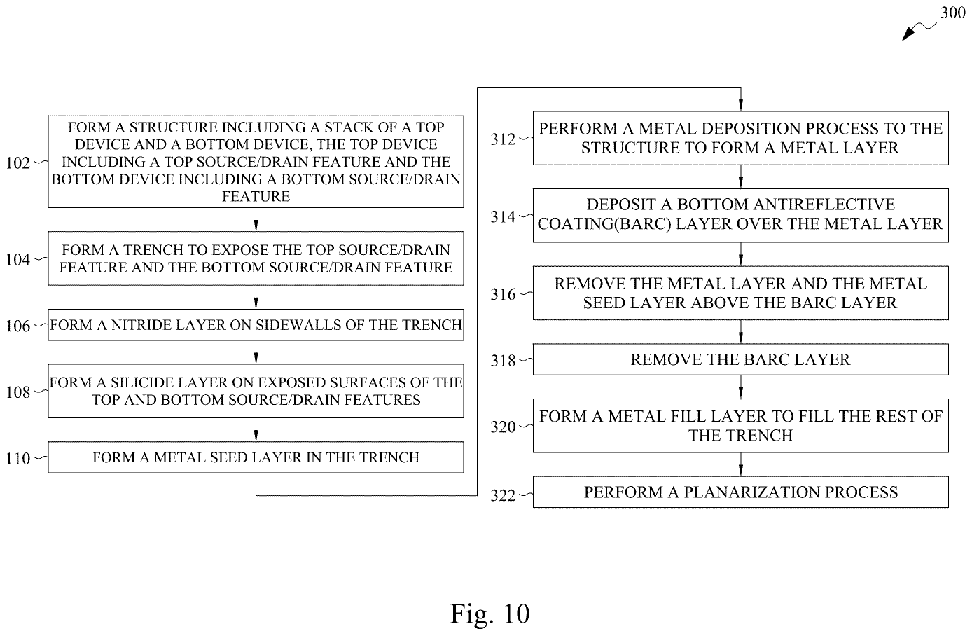

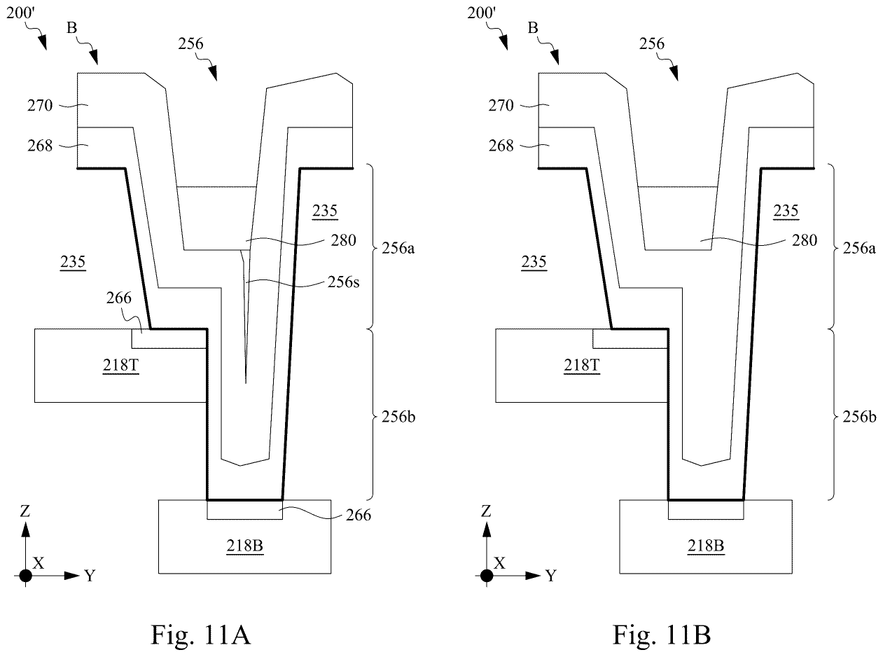

The various aspects of the present disclosure will now be described in more detail with reference to the figures. In that regard, FIG. 1 is a flowchart illustrating method 100 of forming a semiconductor structure according to embodiments of the present disclosure. Method 100 is described below in conjunction with FIGS. 2-9. FIGS. 2-4A and 8-9 are fragmentary cross-sectional views of a structure 200 at different stages of fabrication according to embodiments of method 100 in FIG. 1. FIGS. 4B-7B are fragmentary schematic cross-sectional views of the structure 200 at different stages of fabrication according to embodiments of method 100 in FIG. 1. FIG. 10 is a flowchart illustrating method 300 of forming a semiconductor structure according to embodiments of the present disclosure. Method 300 is described below in conjunction with FIGS. 11A-14B, which are fragmentary schematic cross-sectional views of an alternative structure 200′ at different stages of fabrication according to embodiments of method 300 in FIG. 10. Method 100 (or 300) is merely an example and is not intended to limit the present disclosure to what is explicitly illustrated in method 100 (or 300). Additional steps can be provided before, during and after method 100 (or 300), and some steps described can be replaced, eliminated, or moved around for additional embodiments of method 100 (or 300). Not all steps are described herein in detail for reasons of simplicity. Because the structure 200 (or 200′) will be fabricated into a semiconductor structure, the structure 200 (or 200′) may be referred to herein as a semiconductor structure 200 (or 200′) or a semiconductor device 200 (or 200′) as the context requires. For avoidance of doubts, the X, Y and Z directions in FIGS. 2-14B are perpendicular to one another and are used consistently throughout the present disclosure. Throughout the present disclosure, like reference numerals denote like features unless otherwise excepted. That is, material properties and comparisons thereof for various numbered elements described in association with a method or a figure should apply to the same numbered elements described in association with a different method or a different figure.

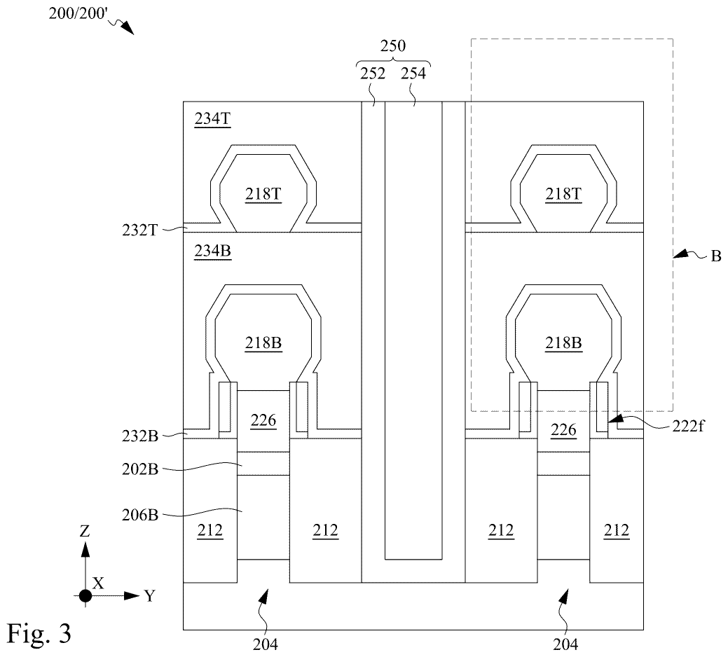

Referring to FIGS. 1-3, method 100 includes a block 102 where a structure 200 is formed or provided. FIG. 3 illustrates a fragmentary cross-sectional view of the structure 200 taken along line A-A′ as in FIG. 2. In some embodiments represented in FIG. 2, the structure 200 includes front-end-of-line (FEOL) CFET structures fabricated on a substrate 202. In the depicted embodiments, the FEOL CFET structures include bottom device structures formed around bottom channel members 2080B and top device structures formed around top channel members 2080T. Along a vertical direction (i.e., the Z direction), the bottom channel members 2080B are spaced apart from the top channel members 2080T by a middle dielectric layer 210 sandwiched between two middle semiconductor layers 2080M. The bottom channel members 2080B are disposed over a base fin 202B. The base fin 202B is disposed over a bottom silicon germanium layer 206B over the substrate 202. An isolation feature 212 (shown in FIG. 3) is disposed over the substrate 202 and surrounds the base fin 202B and the bottom silicon germanium layer 206B. In some embodiments, the bottom silicon germanium layer 206B is omitted. The bottom channel members 2080B constitute channel regions that extend horizontally between two bottom source/drain features 218B. Similarly, the top channel members 2080T constitute channel regions extend horizontally between two top source/drain features 218T. The bottom source/drain features 218B and the top source/drain features 218T may be collectively or individually referred to as source/drain feature(s) 218 as the context requires. The bottom device structures include bottom gate structures 220B that wrap around each of the vertical stack of bottom channel members 2080B and the top device structures include top gate structures 220T that wrap around each of the vertical stack of top channel members 2080T. The bottom gate structures 220B and the top gate structures 220T may be collectively or individually referred to as gate structure(s) 220 as the context requires.

Each of the top source/drain features 218T is disposed directly over one of the bottom source/drain features 218B. The bottom source/drain feature 218B may be disposed on a base epitaxial region 226. As shown in FIG. 2, a bottom source/drain feature 218B is spaced apart from an overlying top source/drain feature 218T by a bottom contact etch stop layer (BCESL) 232B and a bottom interlayer dielectric (BILD) layer 234B. The BILD layer 234B is spaced apart from the middle semiconductor layers 2080M and the middle dielectric layer 210 by the BCESL 232B. A top contact etch stop layer (TCESL) 232T and a top interlayer dielectric (TILD) layer 234T are disposed over each of the top source/drain features 218T. The bottom channel members 2080B are stacked one over another along the Z-direction and are interleaved by inner spacer features 228. Similarly, the top channel members 2080T are stacked one over another along the Z direction and are interleaved by the inner spacer features 228. A gate spacer 222 extends along sidewalls of a portion of the top gate structure 220T above the top channel members 2080T. Due to a planarization process, top surfaces of the TCESL 232T, the TILD layer 234T, the gate spacer 222, and the top gate structures 220T are coplanar. As illustrated in FIG. 2, the bottom channel members 2080B and the top channel members 2080T fall within channel regions 204C of an active region 204 and the bottom source/drain features 218B and the top source/drain features 218T fall within source/drain regions 204SD of the active region 204. A source/drain region 204SD is disposed between two channel regions 204C and a channel region 204C is disposed between two source/drain regions 204SD.

In some embodiments, the substrate 202 may be a silicon (Si) substrate. In some other embodiments, the substrate 202 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 202 may also include an insulating layer, such as a silicon oxide layer, to have a silicon-on-insulator (SOI) structure. The base fin 202B may share the same composition as the substrate 202. In some embodiments, the bottom channel members 2080B, the middle semiconductor layers 2080M, and the top channel members 2080T may include silicon (Si). The gate spacer 222, the middle dielectric layer 210 and the inner spacer features 228 may include silicon oxide, silicon nitride, silicon oxycarbide, silicon oxycarbonitride, silicon carbonitride, metal nitride, or a suitable dielectric material. The BCESL 232B and the TCESL 232T may include silicon nitride or aluminum nitride. The BILD layer 234B and the TILD layer 234T may include an oxide-based dielectric material, such as silicon oxide, fluorine-doped silicate glass (FSG), a low-k dielectric, combinations thereof, and/or other suitable materials. The BCESL 232B and the TCESL 232T may be thinner than the BILD layer 234B and the TILD layer 234T along the X direction, respectively. The isolation feature 212 may include an oxide-based dielectric material, such as silicon oxide, fluorine-doped silicate glass (FSG), a low-k dielectric, combinations thereof, and/or other suitable materials.

The base epitaxial regions 226 may include undoped semiconductor material. In the depicted embodiments, the base epitaxial regions 226 include undoped silicon (Si), undoped silicon germanium (SiGe), or undoped germanium (Ge). A top surface of the base epitaxial regions 226 may be at a same level as a top surface of the base fin 202B. The base epitaxial regions 226 may reduce leakage into the substrate 202. In some embodiments, fin spacers 222f are disposed along sidewalls of the base epitaxial regions 226. The fin spacers 222f and the gate spacer 222 may be formed from the same material.

In the embodiments represented in the figures, the bottom source/drain features 218B are p-type and may include silicon germanium (SiGe) doped with a p-type dopant, such as boron (B); the top source/drain features 218T are n-type and may include silicon (Si) doped with an n-type dopant, such as phosphorus (P) or arsenic (As). In these depicted embodiments, the bottom source/drain features 218B may include boron doped silicon germanium (SiGe:B) and the top source/drain features 218T may include phosphorus doped silicon (Si:P). As used herein, source/drain region, source/drain feature, epitaxial source/drain, epitaxial source/drain feature, etc. may refer to a source of a device, a drain of a device, or a source and/or a drain of multiple devices.

In some embodiments, each of the bottom gate structures 220B and the top gate structures 220T includes an interfacial layer 236 to interface the bottom channel members 2080B, the top channel members 2080T, the middle semiconductor layers 2080M, and/or the base fin 202B. In some embodiments, each of the bottom gate structures 220B and the top gate structures 220T further includes a gate dielectric layer 238 over the interfacial layer 236, and a gate electrode 240 over the gate dielectric layer 238. The gate electrode 240 in the bottom gate structure 220B includes a p-type work function layer. The gate electrode 240 in the top gate structure 220T includes an n-type work function layer. In some embodiments, the interfacial layer 236 includes silicon oxide. The gate dielectric layer 238 is formed of high-k dielectric materials. As used and described herein, high-k dielectric materials include dielectric materials having a high dielectric constant, for example, greater than that of thermal silicon oxide (˜3.9). The gate dielectric layer 238 may include hafnium oxide. Alternatively, the gate dielectric layer 238 may include other high-k dielectrics, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), hafnium lanthanum oxide (HfLaO), lanthanum silicon oxide (LaSiO), aluminum silicon oxide (AlSiO), hafnium tantalum oxide (HfTaO), hafnium titanium oxide (HfTiO), combinations thereof, or other suitable material. In some embodiments, a dielectric constant of the gate dielectric layer 238 is greater than a dielectric constant of the isolation feature 212, the inner spacer features 228, the middle dielectric layer 210, the gate spacer 222, the BCESL 232B, the BILD layer 234B, the TCESL 232T, and the TILD layer 234T. In some instances, the dielectric constant of the gate dielectric layer 238 is more than twice of the dielectric constant of the isolation feature 212, the inner spacer features 228, the middle dielectric layer 210, the gate spacer 222, the BCESL 232B, the BILD layer 234B, the TCESL 232T, or the TILD layer 234T. Further, along the X direction, a thickness of the gate dielectric layer 238 is smaller than a thickness of the gate spacer 222.

By way of example, the p-type work function layer in the gate electrode 240 of the bottom gate structures 220B may include titanium nitride (TiN), tantalum nitride (TaN), ruthenium (Ru), molybdenum (Mo), aluminum (Al), tungsten nitride (WN), zirconium silicide (ZrSi₂), molybdenum silicide (MoSi₂), tantalum silicide (TaSi₂), nickel silicide (NiSi₂), other p-type work function material, or combinations thereof. The n-type work function layer in the gate electrode 240 of the top gate structures 220T may include titanium (Ti), aluminum (Al), silver (Ag), manganese (Mn), zirconium (Zr), titanium aluminum (TiAl), titanium aluminum carbide (TiAlC), tantalum carbide (TaC), tantalum carbonitride (TaCN), tantalum silicide nitride (TaSiN), tantalum aluminum (TaAl), tantalum aluminum carbide (TaAlC), titanium aluminum nitride (TiAlN), other n-type work function material, or combinations thereof. In one embodiment, gate electrodes 240 in the bottom gate structure 220B and the top gate structure 220T include a titanium-based material.

In some embodiments, referring to FIG. 3, the structure 200 includes a gate isolation structure 250. The gate isolation structure 250 may extend lengthwise along the X direction in a top view. In the depicted embodiment, the gate isolation structure 250 is disposed between two active regions 204. The gate isolation structure 250 may separate the gate structure 220 into two portions and electrically isolate the two portions. In some embodiments, the gate isolation structure 250 includes silicon nitride, silicon oxide, silicon oxynitride, silicon oxycarbonitride, silicon oxycarbide, silicon carbonitride, or a combination thereof. In one embodiment, the gate isolation structure 250 includes a silicon nitride liner 252 and a dielectric fill 254 surrounded by the silicon nitride liner 252. The dielectric fill 254 may include silicon oxide.

Referring to FIGS. 1 and 4A, method 100 includes a block 104 where a trench 256 is formed to expose the source/drain features 218. FIG. 4A illustrates a fragmentary cross-sectional view of a portion B of the structure 200 in FIG. 3 at different fabrication stages according to method 100.

The trench 256 may vertically extends through the TILD layer 234T, the BILD layer 234B, the TCESL 232T, and the BCESL 232B to expose both the top source/drain feature 218T and the bottom source/drain feature 218B. In some embodiments, the trench 256 extends through the top source/drain feature 218T. A top surface and sidewall(s) of the top source/drain feature 218T and a top surface of the bottom source/drain feature 218B are exposed in the trench 256. Thus, the trench 256 has a first depth D1 to the top surface of the top source/drain feature 218T and a second depth D2 to the top surface of the bottom source/drain feature 218B. D1 and D2 are along the Z direction and D2 is greater than D1. In the depicted embodiment, the trench 256 includes a top portion 256a having a width W1 and the first depth D1, and a bottom portion 256b having a width W2 and the second depth D2. W1 and W2 are along the Y direction. W1 is greater than W2. In some embodiments, in the cross-sectional view the trench 256 has a “long-short leg” shape, which refers to a shape having a first depth (or a first height, e. g, D1) and a second depth (or a second height, e.g., D2) greater than the first depth, a first width (e.g., W1) of a top portion within the first depth, and a second width (e.g., W2) of a bottom portion between the first depth and the second depth, the second width being less than the first width. The first depth and the second depth are along a first direction (e.g., the Z direction), and the first width and the second width are along a second direction (e.g., the Y direction) perpendicular to the first direction.

In some embodiments, patterning processes are performed to dielectric layers (e.g., the TILD layer 234T, the BILD layer 234B, the TCESL 232T, and the BCESL 232B) to form the trench 256. In some embodiments, a portion of the top source/drain feature 218T is removed in the patterning processes. Forming the trench 256 may include more than one patterning processes to extend the trench 256 to the first depth and the second depth, respectively. The patterning processes may include a plurality of lithography processes and etching processes. The lithography process may include forming a patterned mask layer 262 over the TILD layer 234T. The patterned mask layer 262 may include multiple dielectric layers, such as an etch stop layer (ESL) 258 and an ILD layer 260 stacked one over another as depicted. The patterned mask layer 262 has an opening therein, which overlaps a portion of the respective source/drain region 204SD in a top view. The etching process may include transferring a pattern in patterned mask layer 262 to the dielectric layers therebelow and/or the source/drain feature 218, for example, by removing portions of the TILD layer 234T, the BILD layer 234B, the TCESL 232T, and the BCESL 232B, and/or the source/drain feature 218 exposed by the opening. The etching process may include a dry etch, a wet etch, other suitable etching process, or a combination thereof.

Still referring to FIGS. 1 and 4, method 100 includes a block 106 where a dielectric liner 264 is formed on sidewalls of the trenches 256. The dielectric liner 264 may include a dielectric material such as silicon oxide, silicon nitride, silicon carbide, silicon oxynitride, SiCN films, silicon oxycarbide, SiOCN films, and/or combinations thereof. In some embodiments, the dielectric liner 264 includes silicon nitride. By way of example, the dielectric liner 264 may be formed by blanketly depositing a dielectric material layer in a conformal manner over the structure 200 using processes such as, a chemical vapor deposition (CVD) process, a subatmospheric CVD (SACVD) process, an atomic layer deposition (ALD) process, a physical vapor deposition (PVD) process, or other suitable process. In the illustrated embodiment, the deposition of the dielectric material layer is followed by an etching-back (e.g., anisotropically) process to remove the dielectric material layer from horizontal surface(s) of the trench 256. In some embodiments, the etching-back process may include a wet etch process, a dry etch process, a multiple-step etch process, and/or a combination thereof. In some embodiments, the etching-back process includes a directional etching process. After the etching-back process, the dielectric material layer may remain on sidewalls of the trench 256 as the dielectric liner 264. The dielectric liner 264 prevents diffusion between a metal fill layer (to be described below) and the dielectric layers (e.g., the TILD layer 234T, the TCESL 232T, the BILD layer 234B, the BCESL 232B).

Before proceeding to a next process, a cleaning process may be performed to remove any debris from the surfaces in the trench 256. In some embodiments, the cleaning process includes purging a carrier gas (e.g., an inert gas) to clean the surfaces of the structure 200.

Still referring to FIGS. 1 and 4A, method 100 includes a block 108 where a silicide layer 266 is formed on the exposed surfaces (e.g., the top surfaces) of the bottom source/drain feature 218B and the top source/drain feature 218T. In some embodiments, one or more silicidation processes are performed to form the silicide layer 266. In FIG. 4A, the silicide layer 266 is disposed on each of the exposed top surfaces of the bottom source/drain feature 218B and the source/drain feature 218T, and the silicide layer 266 has a crescent profile. The silicidation process may include depositing a metal-containing layer over the source/drain features 218 by a suitable deposition process and heating the structure 200 (for example, by subjecting it to an annealing process) to cause constituents of the source/drain features 218 to react with metal constituents in the metal-containing layer. In some embodiments, the silicidation process consumes and converts portions of the source/drain features 218 into the silicide layer 266. The metal-containing layer includes any metal constituent suitable for promoting silicide formation, such as nickel, platinum, palladium, vanadium, titanium, cobalt, tantalum, ytterbium, zirconium, other suitable metal, or a combination thereof. The silicide layer 266 thus includes a metal constituent and a constituent of the source/drain features 218 (for example, silicon and/or germanium). In some embodiments, the metal-containing layer is a titanium-containing layer, and the silicide layer 266 includes titanium and silicon and can be referred to as a titanium silicide layers. Any un-reacted metal, such as remaining portions of the metal-containing layer, is selectively removed by any suitable process. The silicide layer 266 formed on the bottom source/drain feature 218B and the top source/drain feature 218T may be formed separately and may include different compositions. For example, a silicide layer 266 is selectively formed on the bottom source/drain feature 218B to have a first composition by a first silicidation process, and then another silicide layer 266 is selectively formed on the top source/drain feature 218T to have a second composition by a second silicidation process. The first composition and the second composition may be different. For example, the silicide layer 266 on the bottom source/drain feature 218B and the silicide layer 266 on the source/drain feature 218T may include different metals. The silicide layer 266 may reduce resistance of a source/drain contact (to be described).

Still referring to FIGS. 1 and 4A, method 100 includes a block 110 where a metal seed layer 268 (also referred to as a metal liner 268) is formed in the trench 256. The metal seed layer 266 is deposited over the structure 200, including over the dielectric liner 264, the patterned mask layer 262, and the silicide layer 266. In some embodiments, the metal seed layer 268 includes molybdenum (Mo), ruthenium (Ru), iridium (Ir), alloys thereof, or a combination thereof. In some embodiments, the metal seed layer deposition is continuous, and a thickness of the metal seed layer 268 is no more than about 5 nm. The metal seed layer 268 may have a thickness of equal to or less than about 5 nm, alternatively less than about 2 nm. The metal seed layer 268 may be formed by a PVD process or an ALD process. In the embodiments where the metal seed layer 268 is formed by a PVD process, a thickness of the metal seed layer 268 on horizontal surfaces (e.g., top surfaces) may be greater than a thickness of the metal seed layer 268 on sidewalls of the trench 256. In the embodiments where the metal seed layer 268 is formed by an ALD process, the metal seed layer 268 may be deposited conformally. The term “conformally” may be used herein for ease of description of a layer having substantially uniform thickness over various regions. The metal seed layer 268 may promote growth or bonding of a metal layer (to be described) formed thereover.

For purposes of simplicity and clarity, FIG. 4B illustrates a simplified schematic view of the structure 200 as in FIG. 4A. In FIG. 4B, a dielectric structure 235 includes the TILD layer 234T, the TCESL 232T, the BILD layer 234B, the BCESL 232B, the patterned mask layer 262, and the dielectric liner 264. In the depicted embodiment, the metal seed layer 268 is disposed on sidewalls and top surfaces of the dielectric structure 235, and top surfaces of the silicide layer 266. In the depicted embodiment, the metal seed layer 268 is thicker on the sidewalls than on the top surfaces of the dielectric structure 235 and the silicide layer 266. The metal seed layer 268 may be formed by a PVD process.

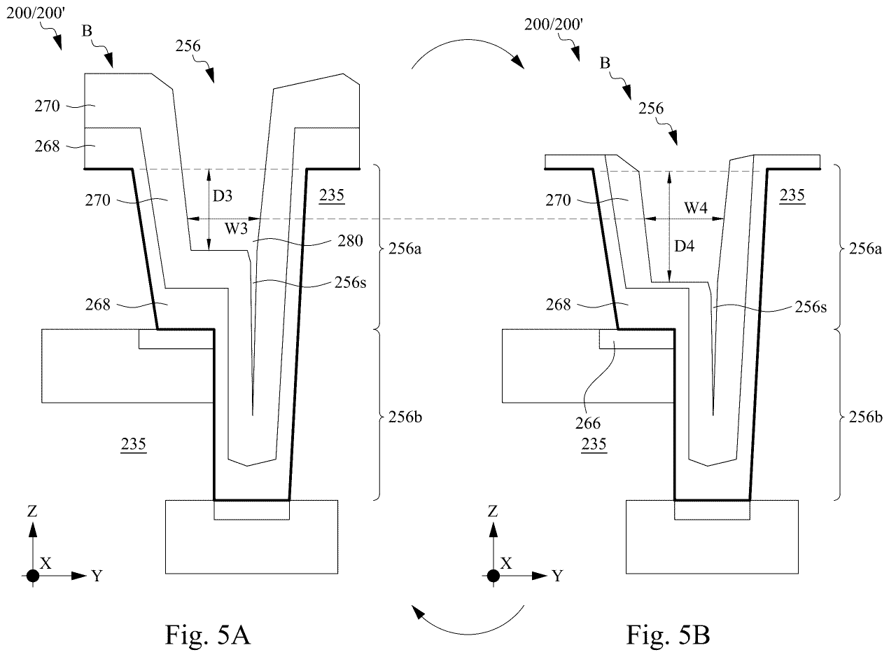

Referring to FIGS. 1 and 5A, method 100 includes a block 112 where a metal deposition process is performed to the structure 200. The metal deposition process may be at a temperature of about 100 degree C. to about 600 degree C. In some embodiments, the metal deposition process includes a suitable deposition process, such as a CVD process or an ALD process. In some embodiments, the metal deposition process includes a CVD process. In some embodiments, the metal deposition process includes flowing a mixture into a process chamber. The mixture may include a metal precursor (also referred to as a metal-containing precursor) and a reactive agent. In some embodiments, the metal precursor includes Mo(CO)₆ (molybdenum hexacarbonyl), MoO₂(thd)₂ (dioxobis(2,2,6,6-tetramethylheptane-3,5-dionato)molybdenum(VI)), MoCl₅ (molybdenum (V) chloride), MoO₂Cl₂ (molybdenum dichloride dioxide), [C₂H₅Ru(CO)₂]₂, Ru(CO)H₂[P(C₆H₅)₃]₃, Ru(TMM)(CO)₃ (tricarbonyl(trimethylenemethane)ruthenium), Ru₃(CO)₁₂ (triruthenium dodecacarbonyl), TICP (C₁₈H₂₇IrO₃ or tricarbonyl (1,2,3-η)-1,2,3-tri(tert-butyl)-cyclopropenyl iridium), or a combination thereof. In some embodiments, a metal in the metal precursor is the same as a metal in the metal seed layer 268. For example, the metal precursor and the metal seed layer 268 include Mo. The reactive agent may interact (e.g., react) with the metal precursor to reduce the metal precursor into elemental metal (e.g., metal atoms not bonded to non-metal elements such as carbon or oxygen), thereby forming a metal layer 270. The reactive agent may include a reactive gas, a plasma, or a combination thereof. In some embodiments, the reactive agent includes a reactive gas, such as hydrogen (H₂). The reactive gas may be referred to as a reducing agent. In some embodiments, the reactive agent includes a plasma generated from gases such as a noble gas (e.g., argon (Ar)). The plasma may break the bonds in the metal precursor to convert the metal precursor into elemental metal. In such embodiments, the metal deposition process includes a plasma enhanced CVD (PECVD) process.

In some embodiments, because of dimensions (e.g., depths, widths) and the shape of the trench 256 and inherency of the deposition process (e.g., the CVD process), the metal layer 270 grows faster in the top portion 256a of the trench 256 than in the bottom portion 256b of the trench 256. A top portion of the metal layer 270 may block the mixture from flowing down into a portion of the trench 256 therebelow. In some embodiments, a seam 256s is formed and sandwiched by the metal layer 270 as depicted. The seam 256s may span from the top portion 256a to the bottom portion 256b of the trench 256. In some embodiments, a remaining portion of the trench 256 above the seam 256s has a width W3 along the Y direction and a depth D3 along the Z direction. In some other embodiments, the operations at block 112 may not result in a seam sandwiched between the metal layer 270.

Referring to FIGS. 1 and 5B-6, method 100 includes a block 114 where a metal self-etch process is performed. The metal self-etch process may remove top portions of the metal layer 270 and the metal seed layer 268 by the metal precursor. As the metal precursor may form a metal layer (e.g., the metal layer 270) and may etch the metal layer, such a property may be referred to as a self-etching property.

The metal self-etch process may be at a temperature of about 100 degree C. to about 600 degree C. In some embodiments, performing the metal self-etch process includes flowing an etching gas in the process chamber. The etching gas includes the metal precursor. The metal precursor used at block 114 and block 112 may have the same composition. In some embodiments, the metal precursor converts the metal layer 270 and/or the metal seed layer 268 into metal-containing gases (e.g., Mo(CO)₄, Mo(CO)₅), which may be purged out of the process chamber (e.g., by unreacted etching gas). For example, the metal layer 270 and the metal seed layer 268 each include elemental Mo, the metal precursor includes Mo(CO)₆, and Mo(CO)₆ reacts with elemental Mo to form Mo(CO)₄ and/or Mo(CO)₅, which are in gas phase at the operation condition. In some embodiments, the metal precursor has a first concentration in the mixture and a second concentration in the etching gas. The first concentration may be lower than the second concentration. In some embodiments, the second concentration is greater than about 95%. In some embodiments, the reactive agent as described above has a concentration of less than about 3% in the etching gas. In some embodiments, the etching gas further includes a carrier gas, such as an inert gas, such as an argon-containing gas, a helium-containing gas, a xenon-containing gas, other suitable inert gas, or a combination thereof. In some embodiments, a carrier gas is used to deliver the metal precursor gas to the process chamber and/or to purge unreacted etching gas and product gases (e.g., the metal-containing gases) out of the process chamber.

Compared to bottom portions of the metal layer 270 and the metal seed layer 268, the top portions of the metal layer 270 and the metal seed layer 268 are closer to the opening of the trench 256 and are exposed more to the etching gas, thus are removed at a faster rate. In some embodiments, after the metal self-etch process, the metal layer 270 over the top surfaces of the dielectric structure 235 is completely removed. In the depicted embodiment, the metal seed layer 268 on the top surfaces of the dielectric structure 235 is partially removed. Thicknesses of the metal layer 270 (e.g., a horizontal portion over the silicide layer 266 and/or vertical portions along sidewalls of the metal seed layer 268) in the top portion 256a of the trench 256 may be reduced. In some embodiments, the seam 256s is not further extended downward during the metal self-etch process. In some embodiments, access to the seam 256s (e.g., a remaining portion of the trench 256 above the seam 256s) is wider after performing the metal self-etch process. For example, a width W4 along the Y direction of the remaining portion of the trench 256 after the metal self-etch process is greater than W3. W3 and W4 are at a same depth or level as depicted by the dashed line. For example, a depth D4 of the remaining portion of the trench 256 after the metal self-etch process is greater than D3. Accordingly, a vertical height of the seam 256s is reduced. Thus, a profile of the metal layer 270 may be adjusted by the metal self-etch process.

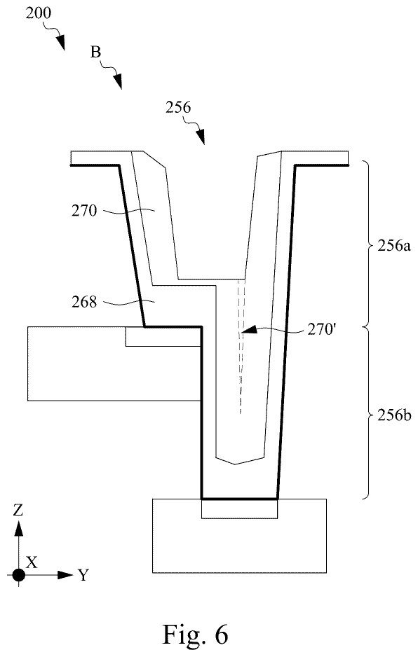

Performing the metal deposition process and performing the metal self-etch process may be in-situ (e.g., in a same process chamber). In some embodiments, a cycle of performing the metal deposition process and performing the metal self-etch process is repeated. For example, after a first cycle of the metal deposition process and the metal self-etch process, the seam 256s may remain (e.g., as in FIG. 5B). Then, a second cycle of the metal deposition process and the metal self-etch process is performed. The metal deposition process of the second cycle may deposit an additional metal layer 270′ over the metal layer 270. The additional metal layer 270′ may fill the seam 256s and/or reduce a size of the seam 256s. In some embodiments, the additional metal layer 270′ completely fill the seam 256s. The additional metal layer 270′ and the metal layer 270 may merge. For simplicity of description, the merged layer of the additional metal layer 270′ and the metal layer 270 is referred to as a merged metal layer 270 or the metal layer 270 that has increased thickness from the metal deposition process of the second cycle. The metal self-etch process of the second cycle may remove a top portion of the merged metal layer 270, including removing a top portion of the additional metal layer 270′. One or more cycles of the metal deposition process and the metal self-etch process may be performed. Similar as described above, each cycle may increase the thicknesses of the metal layer 270 and may remove a top portion of the metal layer 270 in that cycle. The one or more cycles may be performed until the seam 256s is filled by the metal layer 270. In some embodiments, the seam 256s (e.g., shown by the dashed lines in FIG. 6) is completely filled by the metal layer 270 (e.g., as in FIG. 6) after the one or more cycles. In some other embodiments, one or more cycles of the metal deposition process and the metal self-etch process are performed until the seam 256s achieve a designed size. In such embodiments, impact of the seam 256s on resistance of the common source/drain contact may be reduced.

Various parameters of the metal deposition process and the metal self-etch process may be tuned to achieve designed forming and/or etching of the metal layer 270, such as composition of the mixture, composition of the etching gas, the temperatures, the time durations, pressures, gas flow rates, source power, bias power, bias voltage, number of cycles, other suitable parameters, or combinations thereof.

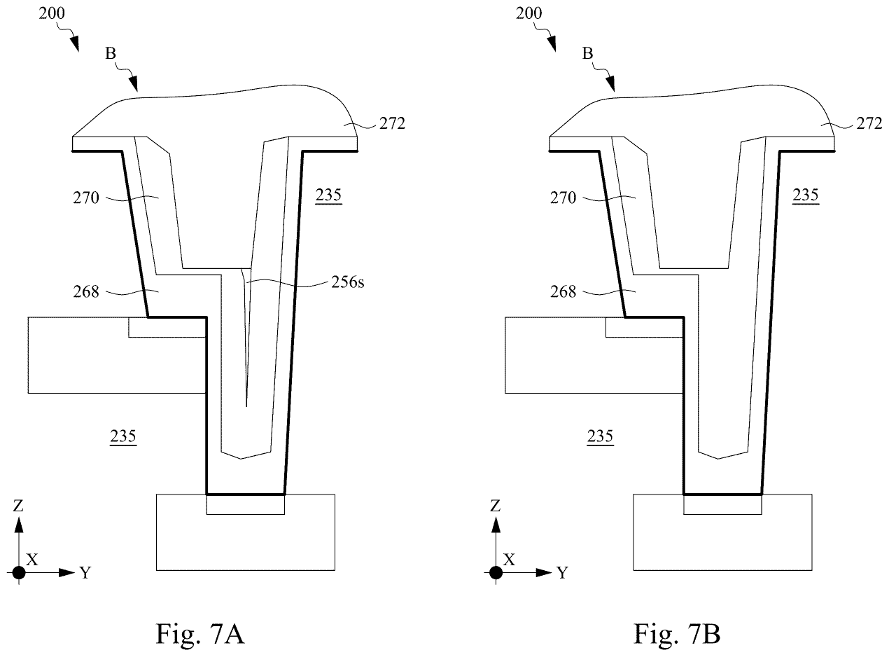

Referring to FIGS. 1 and 7A-7B, method 100 includes a block 116 where a metal fill layer 272 is formed over the structure 200 to fill the trench 256. FIG. 7A represents embodiments where the seam 256s remains and FIG. 7B represents embodiments where the seam 256s is completely filled. Because of the metal self-etch process(es) (e.g., the metal self-etch process in a last cycle), the top portion of the metal layer 270 is removed, thus the remaining portion of the trench 256 may be broadened, and the metal fill layer 272 may be deposited without forming a seam in the metal fill layer 272. The metal fill layer 272 may be deposited over the dielectric structure 235. The metal fill layer 272 may include an elemental metal. In some embodiments, the metal fill layer 272 includes Mo, Ru, Ir, an alloy thereof, or a combination thereof. In some embodiments, the metal fill layer 272 includes the same metal as the metal layer 270. In some embodiments, the metal fill layer 272, the metal layer 270, and the metal seed layer 268 include the same composition. The metal fill layer 272, the metal layer 270, and the metal seed layer 268 may merge. An electrical conductivity of the metal fill layer 272 is greater than an electrical conductivity of the source/drain features 218. In some embodiments, the metal fill layer 272 is formed by CVD, PVD, metalorganic CVD (MOCVD), plating, or other suitable processes.

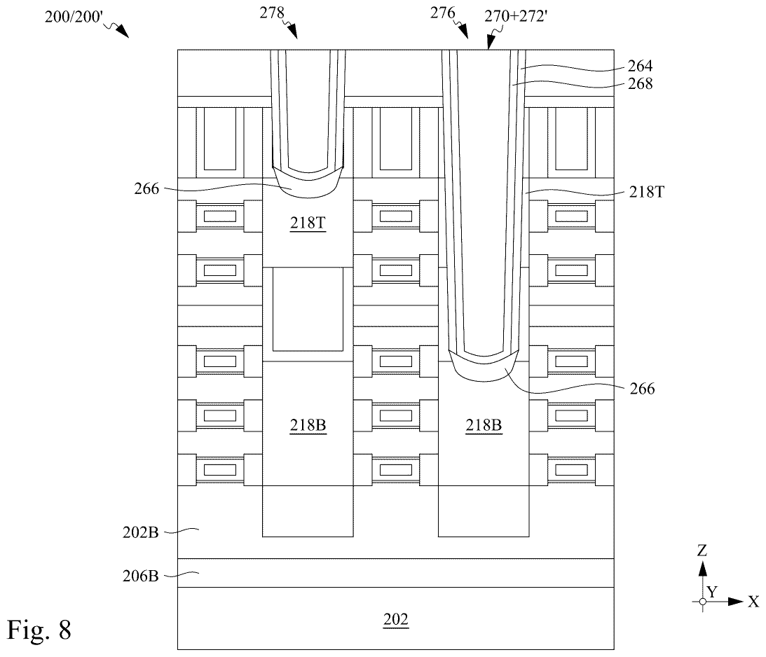

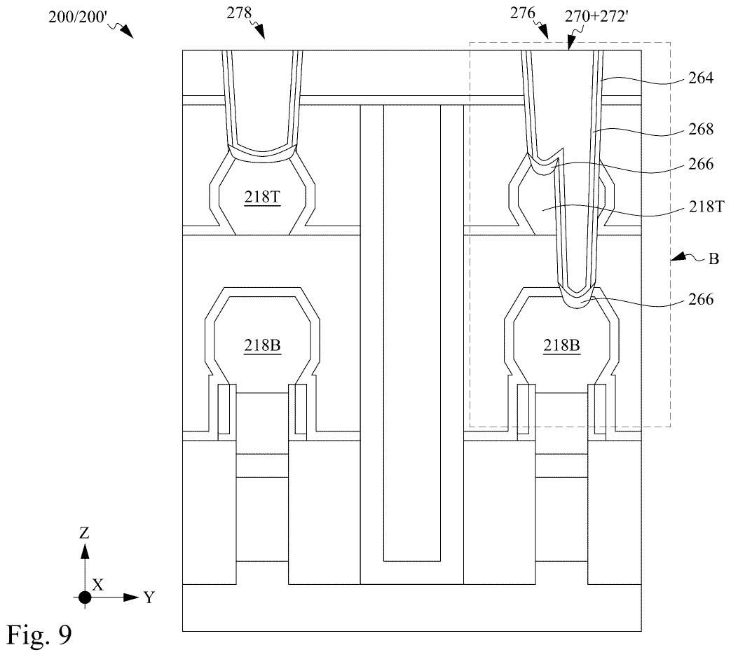

Referring to FIGS. 1 and 8-9, method 100 includes a block 118 where a planarization process (e.g., a CMP process) is performed to remove excess materials (e.g., portions of the metal fill layer 272 and the metal seed layer 268 on the top surfaces of the dielectric structure 235). A remaining portion of the metal fill layer 272 may be referred to as a remaining metal fill layer 272′. The remaining metal fill layer 272′, the metal layer 270, the metal seed layer 268, and the silicide layer 266 collectively form a first source/drain contact 276 (or a common source/drain contact 276). The first source/drain contact 276 has a “long-short leg” shape as described above. A second source/drain contact 278 disposed over and connected to the top source/drain feature 218T but not connected to the bottom source/drain feature 218B may be formed by the same or different methods, and may include similar features, such as a silicide layer, a metal seed layer, and a metal fill layer. Although not explicitly depicted in FIGS. 8-9, the seam 256s may exist in the remaining metal fill layer 272′, resulting from the embodiment represented by FIG. 7A. In some other embodiments resulting from the embodiments represented by FIG. 7B, the first source/drain contact 276 is seamless. By performing one or more cycles of the metal deposition process and the metal self-etch process, a seam in the first source/drain contact 276 may be reduced or avoided, thus resistance of the first source/drain contact 276 is reduced.

The structure 200 may undergo further processes to form various features and regions known in the art. For example, subsequent processing may form additional interlayer dielectric (ILD) layer(s), contacts/vias/lines and multilayers interconnect features (e.g., metal layers and interlayer dielectrics) over the substrate 202, configured to connect the various features to form a functional circuit that may include one or more devices including the semiconductor device 200. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure.

Referring to FIGS. 10-14, method 300 may be used to fabricate an alternative structure 200′. Referring to FIG. 10 and FIGS. 2-4B, the alternative structure 200′ may undergo the operations at blocks 102 to 110 as described above. Referring to FIGS. 10 and 5A, method 300 includes a block 312 where a metal deposition process is performed to the structure 200′ similarly as the operations at block 112. Differences from the metal deposition process at block 112 include follows. In some embodiments, a pressure of the metal deposition process at block 312 is lower than a pressure of the metal deposition process at block 112. Compared to the metal deposition process at block 112, in the metal deposition process at block 312, the mixture diffuses more towards the bottom portion 256b of the trench 256, thus avoiding the forming or reducing the size of the seam 256s. In some embodiments, the metal deposition process at block 312 includes an ALD process. In some embodiments, the metal layer 270 is deposited conformally.

Referring to FIGS. 10 and 11A-11B, method 300 includes a block 314 where a bottom antireflective coating (BARC) layer 280 is deposited over the metal layer 270. A BARC layer material may be deposited over the metal layer 270 using CVD, spin-on processes, or other suitable processes. In some implementations, the BARC layer material may include silicon oxynitride (SiON), silicon oxycarbide, a polymer, or other suitable materials. After the deposition of the BARC layer material, it is selectively etched back to expose a top portion of the metal layer 270 as depicted in FIG. 11A. The etching back may include use of a dry etch process. The dry etch process may include use of plasma of argon (Ar), oxygen (O₂), nitrogen (N₂), hydrogen (H₂), or a combination thereof. A top surface of a remaining BARC layer material (i.e., the BARC layer 280) may be below a top surface of the dielectric structure 235. In the depicted embodiment of FIG. 11A, the seam 256s is enclosed by the metal layer 270 and the BARC layer 280. In some alternative embodiments as in FIG. 11B, no seam is formed below the BARC layer 280.

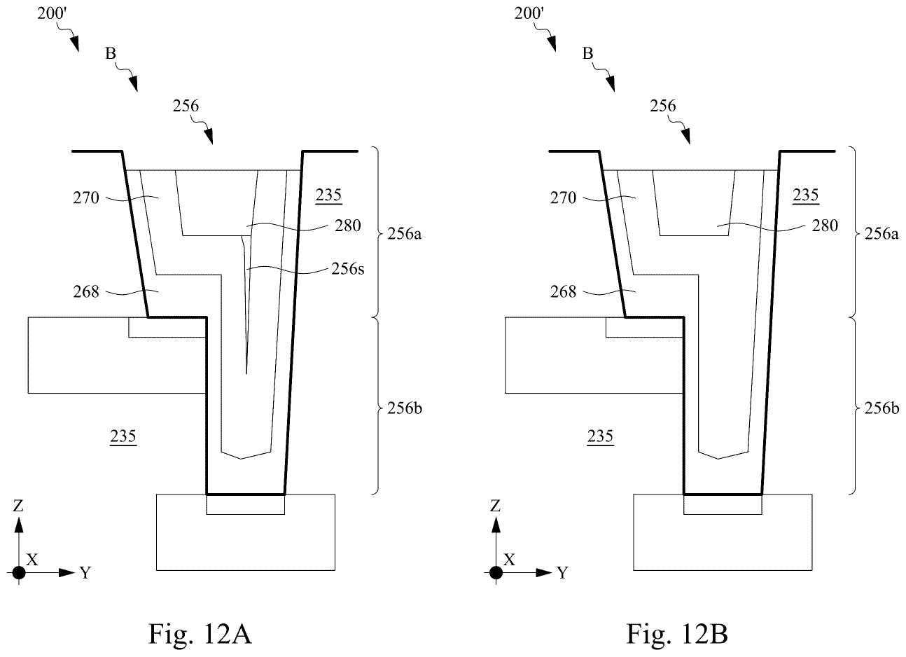

Referring to FIGS. 10 and 12A-12B, method 300 includes a block 316 where top portions of the metal layer 270 and the metal seed layer 268 above the BARC layer 280 are removed. FIGS. 12A and 12B illustrate embodiments resulting from embodiments represented by FIGS. 11A and 11B, respectively. In some embodiments, top portions of the metal layer 270 and the metal seed layer 268 above the top surface of the BARC layer 280 are etched back (or pulled back, e.g., by a wet etching process). After etching back, topmost surfaces of the metal layer 270 and the metal seed layer 268 may be at the same level as the top surfaces of the BARC layer 280. As shown in FIGS. 12A-12B, the etching back removes the top portions of the metal layer 270 and the metal seed layer 268 while the bottom portions of the metal layer 270 and the metal seed layer 268 remain. The etching back provides wider access for depositing the metal fill layer (to be described), thus avoiding additional seam formation in the metal fill layer (e.g., in the top portion 256a of the trench 256, above a top surface of the horizontal portion of the metal layer 270 over the silicide layer 266). The etching back may include a controlled selective etching of the metal layer 270 and the metal seed layer 268 without substantially etching the dielectric structure 235 and the BARC layer 280. For example, as part of the etch-back process, an etchant selectivity may be selected such that metal is etched at a higher rate than dielectric. In some embodiments, the etchant includes phosphoric acid (H₃PO₄), hydrogen chloride (HCl), sulfuric acid (H₂SO₄), nitric acid (HNO₃), hydrogen peroxide (H₂O₂), acetic acid (CH₃COOH), hydrogen fluoride (HF), ammonium hydroxide (NH₄OH), water (H₂O), or a combination thereof.

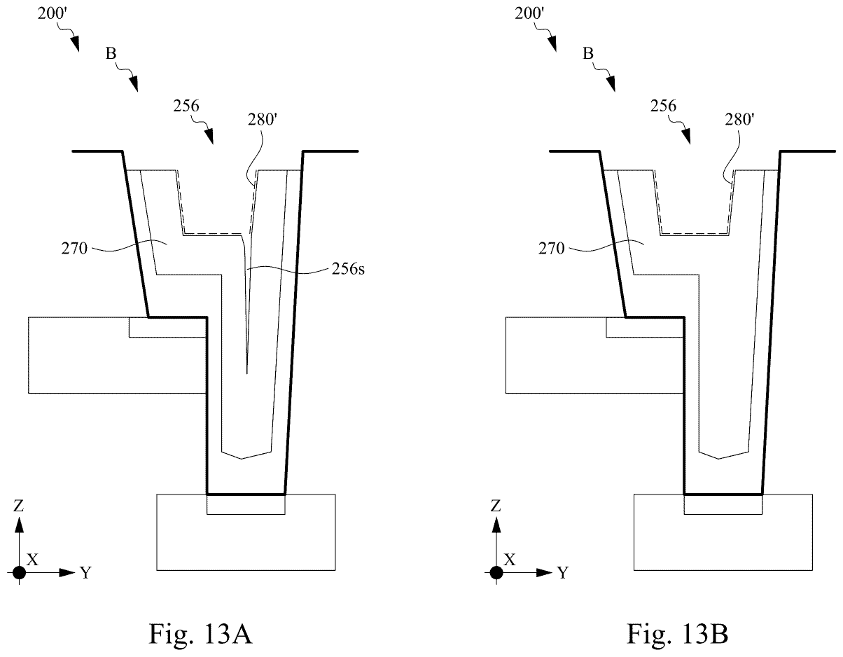

Referring to FIGS. 10 and 13A-13B, method 300 includes a block 318 where the BARC layer 280 is removed using processes such as an ashing process, a wet etch process, and/or a dry etch process. FIGS. 13A-13B illustrate embodiments resulting from embodiments represented by FIGS. 12A and 12B, respectively. In some embodiments, the BARC layer 280 is removed using a wet etch process. In some embodiments, an etchant includes CH₃COOH, HF, NH₄OH, H₂O, H₂O₂, or a combination thereof. A time duration of the etch process at block 318 may be less than a time duration of the etching back process at block 316. In some embodiments, a residue 280′ of the BARC layer 280 remains on the metal layer 270 as illustrated by the dashed lines. The residue 280′ may be detected in the common source/drain feature (to be described). In some embodiments, the residue 280′ has a thickness of less than about 3 nm. In some embodiments, no residue remains on the metal layer 270.

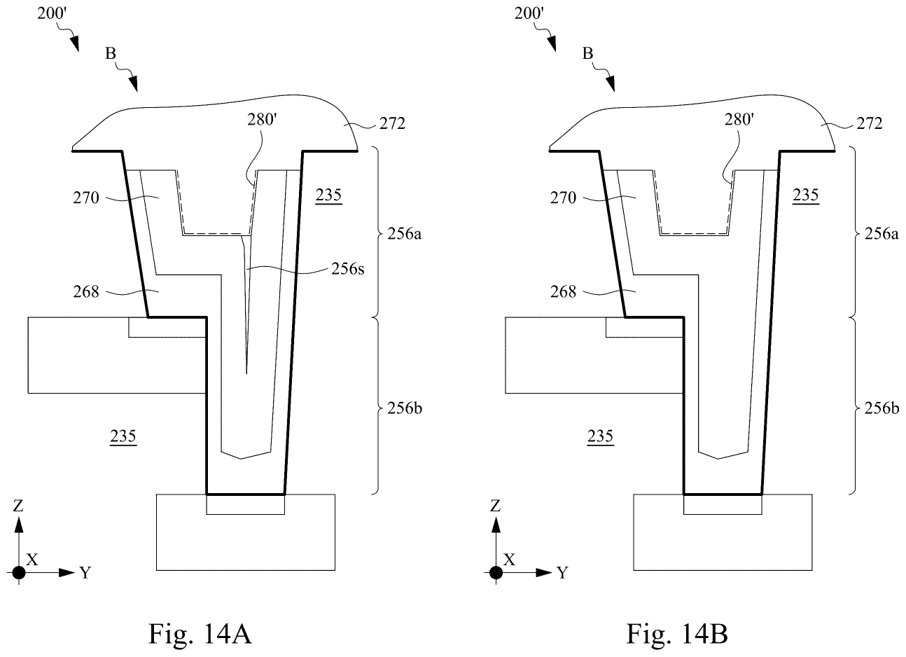

Referring to FIGS. 10 and 14A-14B, method 300 includes a block 320 where the metal fill layer 272 is formed over the metal layer 270. FIGS. 14A-14B illustrate embodiments resulting from embodiments represented by FIGS. 13A-13B, respectively. Differences from embodiments represented by FIGS. 7A and 7B include follows. In FIGS. 14A and 14B, the topmost surfaces of the metal layer 270 and the metal seed layer 268 are below the top surfaces of the dielectric structure 235. In some embodiments, the metal layer 270 in the top portion 256a of the trench 256 has a uniform thickness. In some embodiments, the metal fill layer 272 is directly disposed on a top portion of sidewalls and the top surfaces of the dielectric structure 235. The residue 280′ of the BARC layer 280 on the metal layer 270 is optional and is illustrated in the dashed lines.

Referring to FIGS. 10 and 8-9, method 300 includes a block 322 similar to block 118 in method 100 as described above. Differences include the follows. Because the metal seed layer 268 on the top surfaces of the dielectric structure 235 is removed at block 316, operations at block 322 removes portions of the metal fill layer 272 on the top surfaces of the dielectric structure 235. The seam 256s may exist in the remaining metal fill layer 272′, resulting from the embodiment represented by FIG. 14A. In some other embodiments resulting from the embodiments represented by FIG. 14B, the first source/drain contact 276 is seamless. By forming the BARC layer 280 and performing the etch back process, a seam in the first source/drain contact 276 may be reduced or avoided, thus resistance of the first source/drain contact 276 is reduced. The structure 200′ may undergo further processes as described above to form various features and regions.

Although FIGS. 2-9 and 11A-14B illustrate stacked transistor structures having GAA transistors, other examples of semiconductor devices (e.g., a conductive feature having a long-short leg shape, a conductive feature having a high aspect ratio (e.g., greater than about 4), multigate devices, stacked transistor structures having any combination of transistors, such as planar, FinFET, nanosheet, and nanowire transistors) may benefit from aspects of the present disclosure.

Although not intended to be limiting, one or more embodiments of the present disclosure provide many benefits to a semiconductor structure. For example, by depositing a metal layer in a trench for a common source/drain contact and etching back top portions of the metal layer as described above, a seam may be reduced or excluded in the common source/drain contact, thus the resistance of the common source/drain contact may be reduced. Thus, the overall performance of the semiconductor device may be improved.

In one exemplary aspect, the present disclosure is directed to a method. The method includes providing a structure. The structure includes a bottom source/drain feature, a bottom contact etch stop layer (CESL) disposed over the bottom source/drain feature, a bottom interlayer dielectric (ILD) layer disposed over the bottom CESL, a top source/drain feature disposed over the bottom ILD layer, a top CESL disposed over the top source/drain feature and the bottom ILD layer, and a top ILD layer disposed over the top source/drain feature. A thickness of the bottom CESL is less than a thickness of the bottom ILD layer, a thickness of the top CESL is less than a thickness of the top ILD layer. The method further includes forming a trench extending in the top ILD layer and the bottom ILD layer, the trench exposes the top source/drain feature and the bottom source/drain feature. The method further includes forming a silicide layer on the top and bottom source/drain features, performing a metal deposition process, thereby forming a metal layer on sidewalls and bottom surfaces of the trench, performing a metal self-etch process, thereby removing a top portion of the metal layer, and forming a metal fill layer in the trench.

In some embodiments, performing the metal deposition process includes flowing a mixture including a metal precursor and a reactive agent to the structure, and performing the metal self-etch process includes flowing an etching gas including the metal precursor over the structure. In some embodiments, the metal precursor includes Mo(CO)₆, MoO₂(thd)₂, MoCl₅, MoO₂Cl₂, [C₂H₅Ru(CO)₂]₂, Ru(CO)H₂[P(C₆H₅)₃]₃, Ru(TMM)(CO)₃, Ru₃(CO)₁₂, TICP, or a combination thereof. In some embodiments, the metal precursor has a first concentration in the mixture and a second concentration in the etching gas, the first concentration is lower than the second concentration. In some embodiments, the reactive agent includes a reactive gas, a plasma, or a combination thereof. In some embodiments, the metal deposition process is a first metal deposition process, the metal self-etch process is a first metal self-etch process, and the metal layer is a first metal layer, the method further includes performing a second metal deposition process, thereby forming a second metal layer over a remaining portion of the first metal layer, and performing a second metal self-etch process, thereby removing a top portion of the second metal layer. In some embodiments, before performing the second metal deposition process, the remaining portion of the first metal layer sandwiches seam, the second metal layer fills the seam. In some embodiments, performing the metal deposition process and performing the metal self-etch process are in a same chamber. In some embodiments, performing the metal self-etch process includes flowing a metal precursor over the structure, the metal precursor reacts with the top portion of the metal layer to form a gas including a metal of the metal layer.

In another exemplary aspect, the present disclosure is directed to a method. The method includes providing a structure. The structure includes a bottom active region including a bottom channel region and a bottom source/drain region adjacent to the bottom channel region, a bottom gate structure over the bottom channel region, a bottom contact etch stop layer (CESL) over the bottom source/drain region, a bottom interlayer dielectric (ILD) layer over the bottom CESL, a top active region including a top channel region and a top source/drain region adjacent to the top channel region, a top gate structure over the top channel region, a top CESL over the top source/drain region, and a top ILD layer over the top CESL. The method further includes forming a trench extending through the top ILD layer, the top CESL, the top source/drain region, the bottom CESL, and the bottom ILD layer, to expose the bottom source/drain region, providing a metal precursor to the structure, thereby forming a metal layer in the trench, forming a bottom antireflective coating (BARC) layer over the metal layer and in a top portion of the trench above the top source/drain region, performing an etching process to remove a top portion of the metal layer above the BARC layer, removing the BARC layer, and forming a metal fill layer over a remaining portion of the metal layer and in the trench.

In some embodiments, the metal precursor and the metal fill layer include a same metal. In some embodiments, the BARC layer and the metal layer enclose a seam in a bottom portion of the trench. In some embodiments, before providing the metal precursor to the structure, the method further includes forming a metal seed layer in the trench, the metal layer is formed over the metal seed layer, and performing the etching process further removes a top portion of the metal seed layer above the BARC layer. In some embodiments, an etchant of the etching process includes H₃PO₄, HCl, H₂SO₄, HNO₃, H₂O₂, CH₃COOH, HF, NH₄OH, H₂O, or a combination thereof. In some embodiments, removing the BARC layer leaves a residue BARC layer on the remaining portion of the metal layer.

In yet another exemplary aspect, the present disclosure is directed to a method. The method includes providing a structure including a bottom device and a top device over the bottom device, forming a trench extending through the top device and into the bottom device. The trench includes a bottom portion having a first width and a top portion having a second width, the first width is less than the second width. The method further includes forming a conductive plug in the trench. Forming the conductive plug in the trench includes depositing a metal precursor over the structure, thereby forming a metal layer in the top and bottom portions of the trench, performing an etch-back process to a top portion of the metal layer, filling a metal fill layer in the trench, and performing a planarization process to the structure.

In some embodiments, the bottom device includes a bottom source/drain feature and a bottom dielectric layer disposed over the bottom source/drain feature, the top device includes a top source/drain feature and a top dielectric layer disposed over the top source/drain feature, the conductive plug extends through the top and bottom dielectric layers and electrically connects the top and bottom source/drain features, an electrical conductivity of the conductive plug is greater than electrical conductivities of the top and bottom source/drain features. In some embodiments, the method further includes forming a silicide layer on the top and bottom source/drain features, and between the top and bottom source/drain features and the conductive plug. In some embodiments, performing the etch-back process includes flowing the metal precursor over the structure. In some embodiments, performing the etch-back process includes forming a bottom antireflective coating (BARC) layer on the metal layer and in the trench, performing an etching process to remove the top portion of the metal layer, and removing the BARC layer. The top portion of the metal layer is above the BARC layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
providing a structure comprising:
a bottom source/drain feature,
a bottom contact etch stop layer (CESL) disposed over the bottom source/drain feature,
a bottom interlayer dielectric (ILD) layer disposed over the bottom CESL, wherein a thickness of the bottom CESL is less than a thickness of the bottom ILD layer,
a top source/drain feature disposed over the bottom ILD layer,
a top CESL disposed over the top source/drain feature and the bottom ILD layer, and
a top ILD layer disposed over the top source/drain feature, wherein a thickness of the top CESL is less than a thickness of the top ILD layer;
forming a trench extending in the top ILD layer and the bottom ILD layer, wherein the trench exposes the top source/drain feature and the bottom source/drain feature;
forming a silicide layer on the top and bottom source/drain features;
performing a metal deposition process, thereby forming a metal layer on sidewalls and bottom surfaces of the trench;
performing a metal self-etch process, thereby removing a top portion of the metal layer; and
forming a metal fill layer in the trench.

2. The method of claim 1, wherein performing the metal deposition process comprises flowing a mixture comprising a metal precursor and a reactive agent to the structure, and
wherein performing the metal self-etch process comprises flowing an etching gas comprising the metal precursor over the structure.

3. The method of claim 2, wherein the metal precursor comprises Mo(CO)₆, MoO₂(thd)₂, MoCl₅, MoO₂Cl₂, [C₂H₅Ru(CO)₂]₂, Ru(CO)H₂[P(C₆H₅)₃]₃, Ru(TMM)(CO)₃, Ru₃(CO)₁₂, TICP, or a combination thereof.

4. The method of claim 2, wherein the metal precursor has a first concentration in the mixture and a second concentration in the etching gas,
wherein the first concentration is lower than the second concentration.

5. The method of claim 2, wherein the reactive agent comprises a reactive gas, a plasma, or a combination thereof.

6. The method of claim 1, wherein the metal deposition process is a first metal deposition process, the metal self-etch process is a first metal self-etch process, and the metal layer is a first metal layer,
wherein the method further comprises:
performing a second metal deposition process, thereby forming a second metal layer over a remaining portion of the first metal layer, and
performing a second metal self-etch process, thereby removing a top portion of the second metal layer.

7. The method of claim 6, wherein before performing the second metal deposition process, the remaining portion of the first metal layer sandwiches seam,
wherein the second metal layer fills the seam.

8. The method of claim 1, wherein performing the metal deposition process and performing the metal self-etch process are in a same chamber.

9. The method of claim 1, wherein performing the metal self-etch process comprises flowing a metal precursor over the structure,
wherein the metal precursor reacts with the top portion of the metal layer to form a gas comprising a metal of the metal layer.

10. A method comprising:
providing a structure comprising:
a bottom active region comprising a bottom channel region and a bottom source/drain region adjacent to the bottom channel region,
a bottom gate structure over the bottom channel region,
a bottom contact etch stop layer (CESL) over the bottom source/drain region,
a bottom interlayer dielectric (ILD) layer over the bottom CESL,
a top active region comprising a top channel region and a top source/drain region adjacent to the top channel region,
a top gate structure over the top channel region,
a top CESL over the top source/drain region, and
a top ILD layer over the top CESL;
forming a trench extending through the top ILD layer, the top CESL, the top source/drain region, the bottom CESL, and the bottom ILD layer, to expose the bottom source/drain region;
providing a metal precursor to the structure, thereby forming a metal layer in the trench;
forming a bottom antireflective coating (BARC) layer over the metal layer and in a top portion of the trench above the top source/drain region;
performing an etching process to remove a top portion of the metal layer above the BARC layer;
removing the BARC layer; and
forming a metal fill layer over a remaining portion of the metal layer and in the trench.

11. The method of claim 10, wherein the metal precursor and the metal fill layer comprise a same metal.

12. The method of claim 10, wherein the BARC layer and the metal layer enclose a seam in a bottom portion of the trench.

13. The method of claim 10, before providing the metal precursor to the structure, further comprising forming a metal seed layer in the trench,
wherein the metal layer is formed over the metal seed layer, and
wherein performing the etching process further removes a top portion of the metal seed layer above the BARC layer.

14. The method of claim 10, wherein an etchant of the etching process comprises H₃PO₄, HCl, H₂SO₄, HNO₃, H₂O₂, CH₃COOH, HF, NH₄OH, H₂O, or a combination thereof.

15. The method of claim 10, wherein removing the BARC layer leaves a residue BARC layer on the remaining portion of the metal layer.

16. A method comprising:
providing a structure comprising a bottom device and a top device over the bottom device;
forming a trench extending through the top device and into the bottom device, wherein the trench comprises a bottom portion having a first width and a top portion having a second width, wherein the first width is less than the second width; and
forming a conductive plug in the trench, comprising:
depositing a metal precursor over the structure, thereby forming a metal layer in the top and bottom portions of the trench,
performing an etch-back process to a top portion of the metal layer,
filling a metal fill layer in the trench, and
performing a planarization process to the structure.

17. The method of claim 16, wherein the bottom device comprises a bottom source/drain feature and a bottom dielectric layer disposed over the bottom source/drain feature,
wherein the top device comprises a top source/drain feature and a top dielectric layer disposed over the top source/drain feature,
wherein the conductive plug extends through the top and bottom dielectric layers and electrically connects the top and bottom source/drain features,
wherein an electrical conductivity of the conductive plug is greater than electrical conductivities of the top and bottom source/drain features.

18. The method of claim 17, further comprising forming a silicide layer on the top and bottom source/drain features, and between the top and bottom source/drain features and the conductive plug.

19. The method of claim 16, wherein performing the etch-back process comprises flowing the metal precursor over the structure.

20. The method of claim 16, wherein performing the etch-back process comprises:
forming a bottom antireflective coating (BARC) layer on the metal layer and in the trench,
performing an etching process to remove the top portion of the metal layer, wherein the top portion of the metal layer is above the BARC layer, and
removing the BARC layer.
